(19) United States
(12) Patent Application Publication
(10) Pub. No.: US 2025/0301805 A1
(43) Pub. Date: Sep. 25, 2025

(54) METHOD FOR CROSS-CONNECTING A SOLAR CELL ARRAY, SOLAR PANEL AND DEVICE FOR THE ELECTRICAL CROSS-CONNECTION OF SOLAR CELL ARRAYS

(71) Applicant: M10 Solar Equipment GmbH, Freiburg (DE)

(72) Inventors: Frank Baumann, Kappel-Grafenhausen (DE); Marco SALADIN, Kirchzarten (DE); Dominique JEHL, Rhinau (FR); Philipp Donatus Martin ZAHN, Freiburg (DE); Martin SCHULTIS, Waldkirch (DE)

(73) Assignee: M10 Solar Equipment GmbH, Freiburg (DE)

(21) Appl. No.: 18/864,113

(22) PCT Filed: Mar. 24, 2023
(86) PCT No.: PCT/EP2023/057727

§ 371 Date: Nov. 8, 2024

(30) Foreign Application Priority Data
May 10, 2022 (DE) 10 2022 111 597.6

(51) Int. Cl. H10F 19/90; C09J 5/00; C09J 9/02; H10F 71/00

(52) U.S. Cl. CPC H10F 19/906; C09J 5/00; C09J 9/02; H10F 71/1375; C09J 2203/322

(57) ABSTRACT

In the technical field of solar panel (1) manufacturing, a method is proposed for cross-connecting a solar cell array (2) of crystalline solar cells (3), in which at least one cross-connector (4, 9) of electrically conductive adhesive tape (5, 7) is used for cross-connection.

### CROSS-REFERENCE TO RELATED APPLICATIONS

This application is a 371 National Phase of PCT/EP2023/057727, filed Mar. 24, 2023, which claims priority from German Patent Application No. 10 2022 111 597.6, filed May 10, 2022, both of which are incorporated herein by reference as if fully set forth.

### TECHNICAL FIELD

The invention relates to a method for cross-connecting a solar cell array made of crystalline solar cells, a solar panel having such a solar cell array and a device for cross-connecting solar cell arrays made of crystalline solar cells.

### BACKGROUND

The cross-connection of crystalline solar cell arrays has so far been carried out using copper strips, which have to be soldered after being laid in order to establish an electrical connection to the solar cells. If the solar cell arrays comprise many strings of solar cells that are to be cross-connected, a correspondingly high number of solder connections must be made, which can be relatively laborious. When soldering the copper strips, heat can also be introduced into the solar cells, which can lead to stresses and possibly damage to the solar cells.

### SUMMARY

It is therefore the object of the invention to provide a method for cross-connecting a solar cell array of crystalline solar cells, a solar panel having such a solar cell array and a device for electrical cross-connection of solar cell arrays of crystalline solar cells, which favor an efficient and thus economical and at the same time also gentle cross-connection of solar cell arrays and thereby simplify the production of solar panels.

To solve the object, a method for cross-connecting a solar cell array of crystalline solar cells is first proposed, which has one or more of the means and features disclosed herein directed to such a method. To solve the object, a method is thus proposed for cross-connecting a solar cell array comprising crystalline solar cells, in which at least one cross-connector made of electrically conductive adhesive tape is used for cross-connecting the solar cell array.

By using an electrically conductive adhesive tape to provide a cross-connector for the cross-connection of the solar cell array, the comparatively complex soldering of contact points to copper strips, which were previously used as cross-connectors for cross-connection, can be dispensed with. In the simplest case, the at least one cross-connector can be an adhesive strip made of electrically conductive adhesive tape. Such an adhesive strip can simply be removed from a roll and cut to the required length. This can considerably simplify the provision and application of the cross-connectors.

The cross-connection with a cross-connector made of electrically conductive adhesive tape can be carried out without heat input into the solar cells of the solar cell array. This protects the solar cell array during cross-connection and reduces waste during the manufacture of solar panels.

A further advantage of the method according to the invention is that a cross-connector made of electrically conductive adhesive tape can be applied considerably faster than a copper tape, which has to be soldered at a large number of individual contact points, and also requires less mechanical effort. This favors the economic implementation of the method and thus the efficient production of solar panels.

In one embodiment of the method, it is provided that at least one cross-connector made of electrically conductive adhesive tape is bonded to a row of solar cells. In particular, this can be carried out in such a way that the cross-connector extends within the row without contacting adjacent rows. In this way, a short circuit between adjacent rows is avoided.

In one embodiment of the method, it is provided that at least one cross-connector made of electrically conductive adhesive tape is bonded to a sunny side of a row of a solar cell array. It is also possible to stick at least one cross-connector made of electrically conductive adhesive tape to a rear side of a row facing away from the sunny side.

In one embodiment of the method, at least one cross-connector, for example an initial cross-connector explained in more detail below, is bonded to a sunny side of a row of solar cells of the solar cell array. At least one further cross-connector can then be bonded to a rear side of one of the rows, for example an edge-side row of the rows of solar cells of the solar cell array. The cross connector made of an electrically conductive adhesive tape bonded to the back of a row does not cover any photovoltaically effective surface of the row of solar cells on a sunny side of the solar cell array.

In a particularly advantageous embodiment of the method, a cross-connector made of a preferably double-sided, electrically conductive adhesive tape is bonded to a support structure for the solar cell array as an initial cross-connector. For example, a plastic film, preferably an EVA film or a PCB film, can be used as the support structure for the solar cell array. After the initial cross-connector has been bonded to the support structure, the solar cell array can be placed on the initial cross-connector, in particular with an edge-side row of solar cells, and the initial cross-connector can be bonded to a row of the solar cell array.

In this embodiment of the method, it is particularly advantageous if the initial cross-connector consists of a double-sided, electrically conductive adhesive tape. The double-sided electrically conductive adhesive tape can first be stuck to the support structure and thereby fixed to the support structure. The initial cross-connector then no longer needs to be clamped separately so that it retains its position on the support structure.

If the solar cell array is then placed on the support structure, the initial cross-connector retains its position as it adheres to the support structure. On its side facing away from the support structure, the initial cross-connector made of double-sided adhesive tape also has an adhesive surface, which can then be used to connect the initial cross-connector to a row of the solar cell array. The use of such an initial cross-connector can be particularly advantageous for the automated implementation of the method.

In one embodiment of the method, two or more cross-connectors made of electrically conductive adhesive tape are bonded to different rows of solar cells. In particular, if more than two cross-connectors made of electrically conductive adhesive tape are bonded to different rows of solar cells of the solar cell array, the solar cell array can be divided into individual segments with the cross-connectors.

With a corresponding electrical bypass circuit, for example using bypass diodes, the solar cell array can still provide satisfactory performance even when partially shaded. If a segment of the solar cell array is shaded, the shaded segment can be bypassed via the bypass circuit. The output of the remaining solar cells outside the shaded segment of the solar cell array can then continue to generate electricity without excessive interference from the shaded segment.

Preferably, at least two cross-connectors are bonded to different rows at a distance of at least one row, preferably several rows of solar cells, from each other. The distance between two cross-connectors then determines the size of a segment of the solar cell array defined by the cross-connectors.

As a rule, there are gaps between adjacent solar cells in a row. When using cross-connectors made of electrically conductive adhesive tape, the cross-connectors can be visible through these gaps between adjacent solar cells in a row. This can impair the appearance of the solar cell array. In order to avoid such an impairment of the appearance of the solar cell array, gaps between adjacent solar cells in a row can be covered by cover elements, for example by cover strips, in particular by adhesive cover strips. For this purpose, the cover elements can be placed over the gaps between adjacent solar cells. By covering the gaps, the gaps can be visually bridged and/or closed. Preferably, the cover elements are placed over the gaps between adjacent solar cells in a row before a cross-connector made of electrically conductive adhesive tape is bonded to the row. The cross-connector is then bonded over the cover elements onto the solar cells of the row.

With the cover elements, for example cover strips, preferably adhesive cover strips, and the optical sealing of these gaps, it is possible to prevent the cross-connector from being visible through the gaps between adjacent solar cells on the sunny side of the solar cell array. Preferably, the cover elements can have a color that matches the color of the solar cells of the solar cell array. In this context, it is also advantageous if the cover elements have a dimension that can be measured transversely or at right angles to the row orientation of the rows, which is larger than a dimension of the cross-connectors that can be measured in the same direction. This ensures that the cross-connectors can be covered by the cover elements without being visible through the gaps between adjacent solar cells.

In order not to reduce the photovoltaically effective area of the solar cells, it is advisable to apply the cover elements to a rear side of the solar cell array that faces away from a sunny side of the solar cell array.

To connect a cross-connector to a junction box, the cross-connector can be electrically connected to a longitudinal connector. Preferably, the longitudinal connector also consists of an electrically conductive adhesive tape. The longitudinal connector can then be easily bonded to the cross-connector that is to be connected to a junction box. In the simplest case, the longitudinal connector, like the cross-connector(s), can therefore also be an adhesive strip made of electrically conductive adhesive tape. Such an adhesive strip can simply be removed from a roll and cut to the required length. This can considerably simplify the provision and application of longitudinal connectors when carrying out the method.

Two cross-connectors can be connected to a junction box via their longitudinal connectors, for example. The cross-connectors and the longitudinal connectors can thereby be part of a bypass circuit, with which the rows of solar elements of the solar cell array can be bypassed in the event of shading in order not to impair the performance of the remaining solar cells of the solar cell array, which lie outside a segment of the solar cell array defined by the two cross-connectors.

Part of the bypass circuit mentioned above can be a bypass diode. If the electrical resistance increases due to shading of the rows in the segment of the solar cell array defined by the two cross-connectors, the bypass circuit can become active and conduct current past the solar cells of the shaded segment through the remaining solar cells of the solar cell array.

In one embodiment of the method, at least one cross-connector is bonded to a row of the solar cell array in such a way that it protrudes beyond one end of the row. In its protruding area, the cross-connector can then be connected to a longitudinal connector.

In a preferred embodiment of the method, which favors a particularly space-saving cross-connection of the solar cell array, at least one longitudinal connector can be placed, in particular bonded, transversely or at right angles to a row orientation of the solar cell array over the rows of the solar cell array. This is preferably done on a rear side of the solar cell array that faces away from a sunny side of the solar cell array.

It is also possible to place a longitudinal connector transversely or at right angles to a row orientation of the solar cell array on a support structure adjacent to the solar cells of the solar cell array, in particular to glue it on.

In particular, if at least one longitudinal connector is to be placed, in particular bonded, transversely or at right angles to a row orientation of the solar cell array over the rows, it is advantageous to first place, in particular glue, an electrical insulator, in particular an insulating tape, transversely or at right angles to the rows between two cross-connectors. The longitudinal connector can then be placed on, in particular bonded to, the electrical insulator and a cross-connector. The electrical insulator can be used to prevent the longitudinal connector from short-circuiting rows of the solar cell array. The insulating tape can be an adhesive insulating tape made of EPE, for example. An adhesive insulating tape can simply be stuck on and can therefore be attached to the solar cell array without great effort.

The solar cells of the solar cell array can preferably be arranged in a shingle-matrix arrangement.

To solve the object, a solar panel having a solar cell array comprising crystalline solar cells is also proposed, which has on or more of the features disclosed herein directed to such a solar panel. In particular, a solar panel having a solar cell array of crystalline solar cells is thus proposed for solving the object, wherein the solar cell array is cross-connected to at least one cross-connector of electrically conductive adhesive tape.

In one embodiment of the solar panel, at least one cross-connector made of electrically conductive adhesive tape can be bonded to a row of solar cells. This is preferably done without contacting adjacent rows of solar cells.

At least one cross-connector, which is used for cross-connecting the solar panel, can consist of an electrically conductive, double-sided adhesive tape. As previously explained in connection with the method, this cross-connector can be bonded as an initial cross-connector to a support structure of the solar panel for the solar cell array and/or to a sunny side of the solar cell array.

The solar cells of the solar cell array can be arranged in a shingle matrix arrangement. In such a shingle matrix arrangement, the voltage build-up takes place in a direction transverse or at right angles to the row direction of the individual rows of solar cells. An electrical voltage level can be applied within a row of solar cells of the shingle matrix arrangement. The cross-connectors applied to the rows within a row can therefore contact solar cells at which a voltage level is present. This favors the previously explained segmentation of the solar cell array.

The electrical voltage is then built up transversely or at right angles to the alignment of the rows across the rows of the solar cell array. An electrical voltage level can be applied within a row of solar cells of the solar cell array. A row of solar cells in a shingle matrix arrangement can therefore be distinguished from a conventional string of solar cells. In a string of solar cells, the solar cells are arranged and interconnected in such a way that the voltage build-up occurs in the longitudinal direction of the string. In contrast thereto, in a shingle matrix arrangement, no electrical voltage is built up in the longitudinal direction of a row of solar cells.

To connect to a junction box of the solar panel, at least one cross-connector made of electrically conductive adhesive tape can be connected to a longitudinal connector. Such a longitudinal connector can preferably also consist of electrically conductive adhesive tape. This makes it easier to establish an electrical connection between the longitudinal connector and the cross-connector.

The longitudinal connector can extend transversely or at right angles over rows of solar cells that are arranged between two cross-connectors. In one embodiment of the solar panel, a longitudinal connector can also be arranged adjacent to the solar cell array, for example on a support structure of the solar panel for the solar cell array, and may also extend transversely or at right angles to the row direction of the rows of solar cells of the solar cell array.

An insulator can be arranged between the longitudinal connector and the rows of solar cells. For example, an insulating tape, preferably an insulating adhesive tape, can be bonded to the solar cells as an insulator. The insulator can be used to prevent a short circuit that could occur if the longitudinal connector came into direct contact with the solar cells. The insulator can be made of EPE.

Gaps between adjacent solar cells in a row with a cross-connector made of electrically conductive adhesive tape can be covered with cover elements, in particular with cover strips or adhesive cover strips. The cross-connector is then arranged behind the cover elements and is not visible through the gaps. The gaps are then visually closed by the cover elements. In order to be able to conceal the cross-connectors with the cover elements, it is advantageous if the cover elements have a width that can be measured transversely or at right angles to the longitudinal extension of the cross-connector and is at least as large as the width of the cross-connector that can be measured in the same direction.

The cover elements are preferably arranged on a rear side of the solar cell array that faces away from a sunny side of the solar cell array.

Two cross-connectors can be connected to each other via longitudinal connectors and a junction box and/or a bypass circuit, for example with a bypass diode. With the aid of a bypass circuit, it is possible to bypass the solar cells located between two cross-connectors in the event of shading so as not to impair the performance of the other solar cells in the solar panel.

At least one cross-connector made of electrically conductive adhesive tape can be arranged on a sunny side of the solar cell array of the solar panel. It is also possible that at least one cross-connector made of electrically conductive adhesive tape and/or one longitudinal connector, in particular made of electrically conductive adhesive tape, is arranged on a rear side of the solar cell array that faces away from a sunny side of the solar cell array.

The aforementioned cross-connectors and longitudinal connectors can be adhesive strips made of electrically conductive adhesive tape. The aforementioned initial cross-connectors can be adhesive strips made of electrically conductive, double-sided adhesive tape.

To solve the object, a device for the electrical cross-connection of a solar cell array of crystalline solar cells is also proposed, which has one or more of the means and features disclosed herein directed to such a device. The device is set up to carry out the claimed method and has at least one cross-connector applicator which is set up to stick electrically conductive adhesive tape as a cross-connector on rows of a solar cell array.

In one embodiment of the device, it is provided that the device has at least one cover element applicator which is set up for applying, in particular for gluing, cover elements to gaps between adjacent solar cells of a row of a solar cell array.

The device can have at least one longitudinal connector applicator which is set up for applying, in particular for gluing on, longitudinal connectors.

The device can also have at least one insulation applicator for applying, in particular for gluing on, electrical insulators, preferably electrical insulation tape.

In one embodiment of the device, the cross-connector applicator has a supply roll. A supply of electrically conductive adhesive tape for providing cross-connectors can be rolled up on the supply roll. The cross-connector applicator can also have an application element, in particular an application roller, and/or a pressing element. With the aid of the application roller, it is possible to stick the electrically conductive adhesive tape, which has been unrolled from the supply roll, to a surface of solar cells in a row and thereby apply the electrically conductive adhesive tape as a cross-connector to the solar cells in a row. With the aid of the pressure element, which can be designed as a pressure roller, for example, it is possible to press the bonded-on cross-connector made of electrically conductive adhesive tape onto the surface of the solar cells after it has been applied. This can improve the adhesion of the cross-connectors. In this context, it can be advantageous if the pressing element is arranged downstream of the application element in the direction of application of the cross-connectors.

In a similar way, the device can also have a supply roll with cover elements for the cover element applicator, a supply roll with longitudinal connectors for the longitudinal connector applicator and a supply roll with insulators, in particular with insulating tape or insulating adhesive tape, for the insulating applicator.

The cover element applicator, the longitudinal connector applicator and/or the insulation applicator can have application elements, for example application rollers, and/or pressure elements, in particular pressure rollers, which are preferably positioned downstream of the respective application element in the application direction. In this way, it is possible to first apply the respective structure, which is preferably designed as an adhesive strip, for example the cover elements, the insulators and/or the longitudinal connectors, to their target surface using the respective application element and then press them onto the surface to which they were bonded using the downstream pressure element.

In order to protect the solar cells from overloading when applying the cross-connectors, longitudinal connectors, cover elements and/or insulators, the device can be set up for pressure monitoring. Preferably, the device has at least one pressure sensor for at least one cross-connector applicator, for at least one cover element applicator, for at least one insulation applicator and/or for at least one longitudinal connector applicator, preferably in each case, with which the pressure acting on the solar cells during the application of the cross-connectors, cover elements, insulators and/or longitudinal connectors can be monitored. If a permissible maximum pressure is exceeded, the device can reduce the pressure by means of at least one corresponding control unit and prevent damage to the solar cells. Each of the aforementioned applicators can have a corresponding control unit. However, the device can also have a central control unit that can carry out the pressure control or pressure regulation of the applicators described above.

### BRIEF DESCRIPTION OF THE DRAWINGS

The invention is explained in more detail below with reference to exemplary embodiments, but is not limited to these exemplary embodiments. Further exemplary embodiments result from combining the features of individual or several claims with one another and/or in combination of individual or several features of the embodiments, wherein:

FIG. 1 shows a perspective view of a first embodiment of a solar panel having a support structure comprising a glass pane and a plastic film applied to the glass pane, and having a solar cell array applied to the plastic film, wherein three different rows of the solar cell array are bonded with cross-connectors made of electrically conductive adhesive tape for cross-connection of the solar cell array,

FIG. 2 shows a perspective view of a further embodiment of a solar panel, in which the solar cell array of the solar panel is cross-connected to two cross-connectors made of electrically conductive adhesive tape,

FIGS. 3 and 4 show further embodiments of solar panels, in which three cross-connectors and a total of three longitudinal connectors made of electrically conductive adhesive tape are bonded on for cross-connection of the solar cell arrays,

FIG. 5 shows a single-part representation of a glass pane, as used as part of the support structure in the solar panels shown in the previous figures,

FIG. 6 shows a single-part representation of a plastic film, as used as part of the support structure in the solar panels shown in the previous figures, wherein the plastic film is placed on the glass pane shown in FIG. 5,

FIG. 7 shows a support structure for a solar cell array, which consists of a glass pane and a plastic film, wherein a cross-connector made of a double-sided electrically conductive adhesive tape serving as an initial cross-connector is placed on the plastic film,

FIG. 8 shows the support structure shown in FIG. 7 with the initial cross-connector and a shingle-matrix solar cell array, which is placed with its first row of solar cells on the initial cross-connector,

FIG. 9 shows the solar cell array shown in FIG. 8, wherein gaps between solar cells of the rows are optically closed with the aid of cover elements, onto which cross-connectors are subsequently to be bonded,

FIG. 10 shows the solar cell array shown in FIG. 9 with two further cross-connectors made of electrically conductive adhesive tape bonded to a rear side of the solar cell array,

FIG. 11 shows the solar cell array shown in FIG. 10, wherein an insulator in the form of an insulating tape is bonded between two cross-connectors spaced apart by several rows of solar cells,

FIG. 12 shows the solar cell array shown in FIG. 11, wherein each of the cross-connectors is connected to a respective longitudinal connector, and wherein the longitudinal connectors are adhesive strips of electrically conductive adhesive tape which are bonded on one side to the cross-connectors and on the other side to the electrical insulators,

FIG. 13 shows the solar cell array shown in FIG. 12 with junction boxes connected to the cross-connectors,

FIG. 14 shows a solar cell array divided into three segments with an initial cross-connector and three further cross-connectors made of electrically conductive adhesive tape, having two junction boxes in each of which a bypass diode is arranged, and having a flat diode as a bypass diode on a middle one of the three segments, which can be laminated into the finished solar panel,

FIG. 15 shows a sectional side view with a section of a solar panel with a cross-connected solar cell array to illustrate its layered structure,

FIG. 16 shows a perspective view of a cross-connector applicator of a device for cross-connecting solar cell arrays during the application of an initial cross-connector made of electrically conductive adhesive tape,

FIG. 17 shows a perspective view of cover element applicators of the device, which are set up to bridge gaps between adjacent solar cells by gluing on cover elements and thereby close them, so that a cross-connector arranged behind it is no longer visible through the gaps,

FIG. 18 shows a perspective view of cross-connector applicators of the device which are set up to bond cross-connectors made of electrically conductive adhesive tape onto rows of solar cells,

FIG. 19 shows a perspective view of an insulation applicator of the device which is set up to bond electrical insulators, namely electrical insulating adhesive tapes onto solar cells between cross-connectors,

FIG. 20 shows a perspective view of a longitudinal connector applicator of the device, which is set up for bonding longitudinal connectors,

FIG. 21 shows an exemplary embodiment of a device for cross-connecting solar cell arrays, in which a cross-connector applicator is arranged on a robot of the device, and

FIG. 22 shows a further embodiment of a device for cross-connecting solar cell arrays, in which different applicators are suspended on a portal of the device.

### DETAILED DESCRIPTION

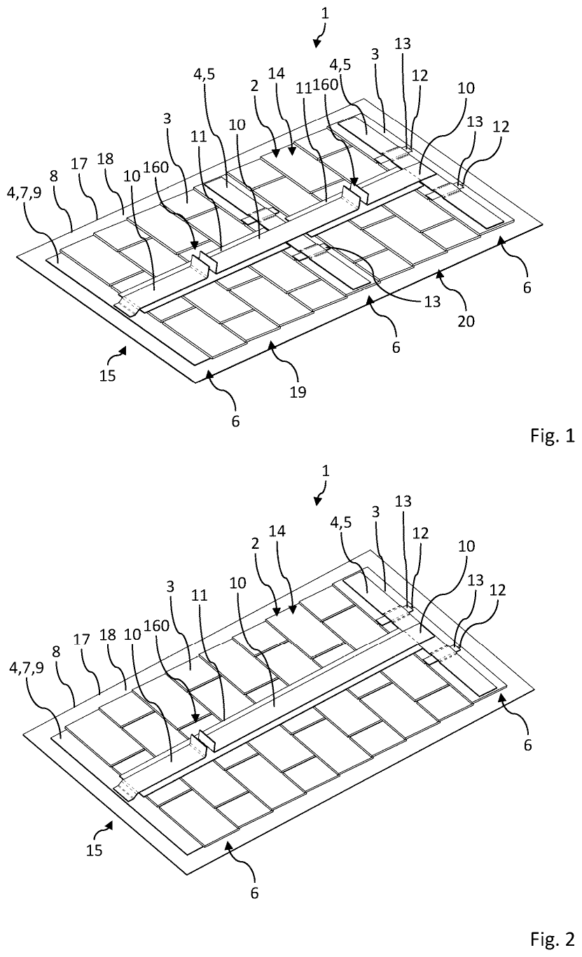

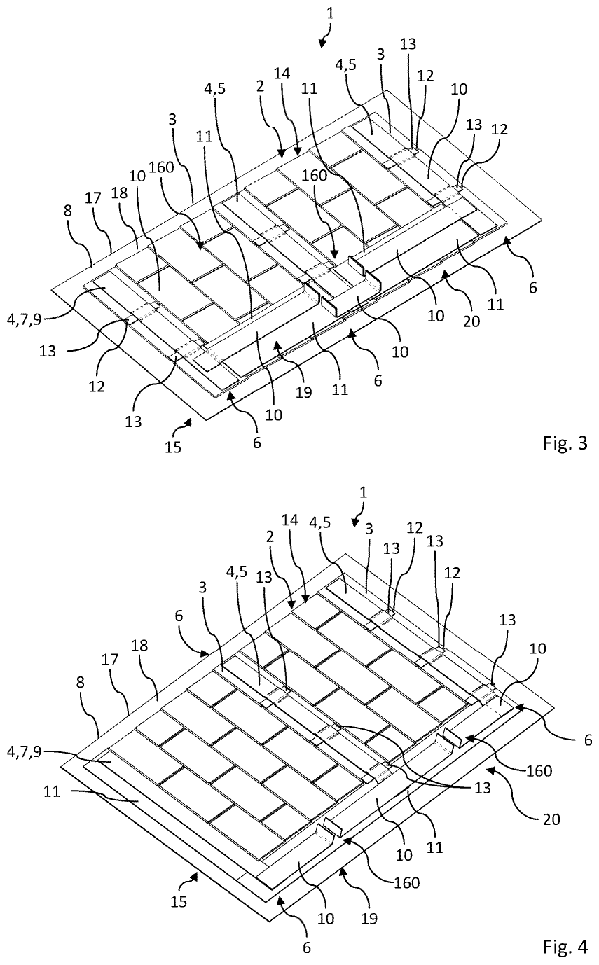

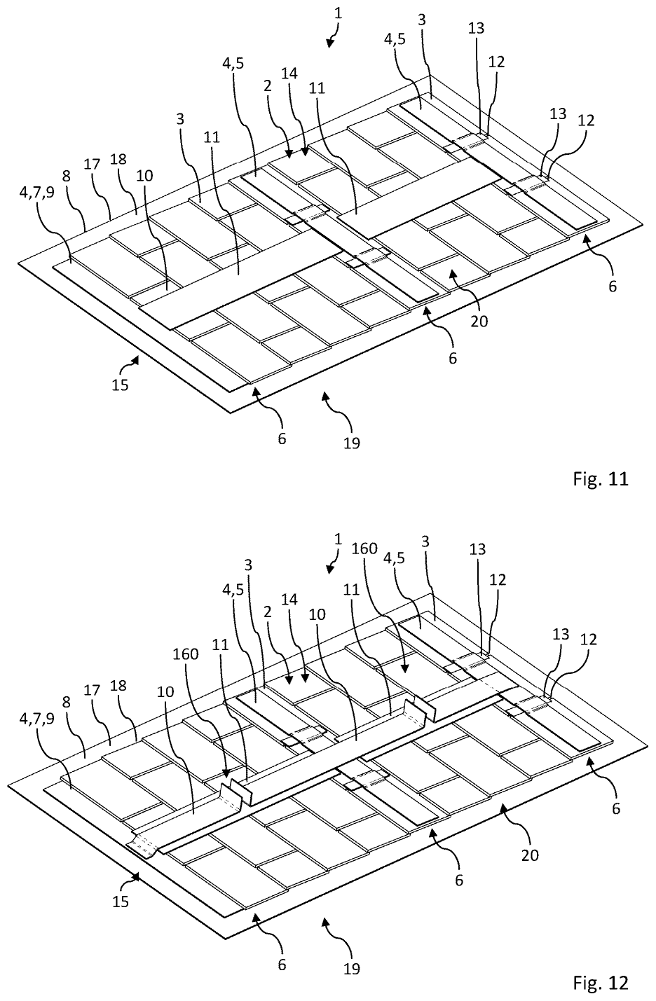

FIGS. 1-15 show at least parts of solar panels labeled 1 in their entirety. The solar panels 1 each have a solar cell array 2 made of crystalline solar cells 3, namely solar cell shingles. The solar cell arrays 2 are cross-connected to cross-connectors 4, 9 made of electrically conductive adhesive tape.

FIGS. 1-15 show that the cross-connectors 4, 9 made of electrically conductive adhesive tape 5, 7 are each bonded to a row 6 of solar cells 3 without contacting adjacent rows of solar cells 3. In each solar panel 1 shown, at least one cross-connector 4 is made of electrically conductive, double-sided adhesive tape 7, which is bonded to a support structure 8 of the solar panel 1 for the solar cell array 2 before the solar cell array 2 is placed on the cross-connector 4 made of double-sided adhesive tape 7. The cross-connector 4 made of electrically conductive, double-sided adhesive tape 7 can also be referred to as the initial cross-connector 9. The initial cross-connector 9 is shown in FIG. 7 on the support structure 8 of a solar panel 1, even before the solar cell array 2 has been placed on the support structure 8 and thus on the initial cross-connector 9 made of double-sided adhesive tape 7.

The figures also illustrate that the solar cells 3 of the solar cell arrays 2 are arranged in a so-called shingle matrix arrangement. Here, two adjacent rows 6 of solar cells 3 are arranged offset from each other on the one hand and on the other hand one row 6 overlaps its adjacent row 6. In this way, the solar cell arrays 2 are given a masonry-like structure which, due to the offset and the overlapping of the solar cells 3 of adjacent rows 6, favors the formation of a large number of current paths within the solar cell arrays 2.

In this context, it is worth mentioning that an electrical voltage build-up takes place transversely or at right angles to an alignment of the rows 6 of the solar cell arrays 2 via the rows 6 of the solar cell arrays 2. An electrical voltage level is then present within a row 6 of solar cells 3 of the solar cell arrays 2. In comparison, the voltage build-up in a conventional string of solar elements takes place in the direction of its longitudinal extension. A conventional string of solar cells can therefore be distinguished from a row of solar cells 3, as found in the solar cell arrays 2 shown.

The cross-connectors 4, 9 made of electrically conductive adhesive tape 5, 7 are each connected to a longitudinal connector 10, which is also made of electrically conductive adhesive tape 5, for connection to a junction box of the respective solar panel 1. FIGS. 1 to 4 show different possibilities for arranging cross-connectors 4, 9 and longitudinal connectors 10 for connecting the solar cell arrays 2 of the solar panel 1.

In all the solar panels 1 shown, the longitudinal connectors 10 extend at right angles to a row orientation of the rows 6 of solar cells 3. In the solar panels 1 shown in FIGS. 1-3, the longitudinal connectors 10 extend at right angles to a row orientation of the rows 6 via rows 6 of solar cells 3.

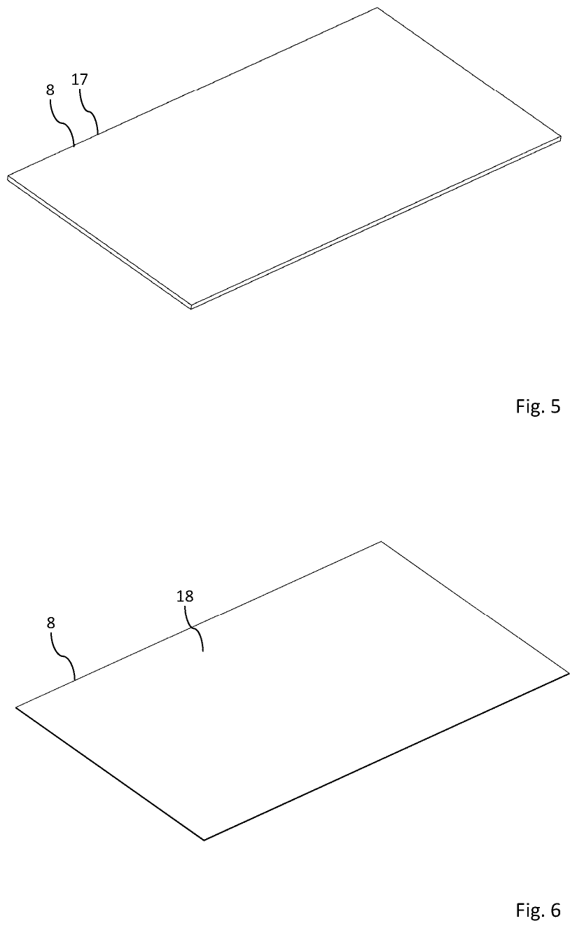

In the exemplary embodiment of a solar panel 1 shown in FIG. 4, the longitudinal connectors 10 are applied adjacent to the solar cell array 2 on the support structure 8 of the solar panel 1 for the solar cell array 2, but nevertheless extend at right angles to the rows 6 of solar cells 3 of the solar cell array 2. In the solar panels 1 shown in FIGS. 1-3, the longitudinal connectors 10 extend at right angles to the rows 6 over the rows 6 of solar cells 3, which are arranged between two cross-connectors 4, 9.

An insulator 11 in the form of an insulating tape, namely an insulating adhesive tape, is arranged between the longitudinal connectors 10 and the rows 6 of solar cells 3. The insulators 11 are bonded to the solar cells 3. The insulators 11 consist of an EPE insulating tape and prevent the longitudinal connectors 10 from short-circuiting the solar cells 3.

FIGS. 1-4 also show that gaps 12 between adjacent solar cells 3 in a row 6 with a cross-connector 4 made of electrically conductive adhesive tape 5 are optically sealed with cover elements 13 in the form of adhesive cover strips. The cover elements 13 are arranged on a rear side 14 of the solar cell arrays 2, which faces away from a sunny side 15 of the solar cell arrays 2. The cover elements 13 are wider than the cross-connectors 4, 9 and prevent the cross-connectors 4 made of electrically conductive adhesive tape 5 from being visible on the sunny side 15 of the solar cell arrays 2 and impairing the overall visual impression of the solar panels 1. In this context, it is advantageous if the cover elements 13 have a similar or even the same color as the solar cells 3 of the solar cell arrays 2.

Two cross-connectors 4, 9 are connected to each other via longitudinal connectors 10 and a junction box 16, which can be arranged, for example, at one of the positions designated 160. The junction box can contain or form a bypass circuit with a bypass diode 38, which enables the solar cells 3 located between two cross-connectors 4,9 to be bypassed in the event of shading. The solar cell arrays 2 can be divided into segments 19, 20 with the aid of the cross-connectors 4, 9.

If one of the segments 19, 20 is shaded or partially shaded, it is possible to bypass the shaded segment(s) 19, 20 via a bypass circuit with a bypass diode 38. In the event of shading, the electrical resistance of the solar cells 3 located in the shaded segment 19, 20 can increase so that the bypass diode 38 switches and releases a current path past the shaded segment 19, 20. In this way, the shaded segment 19, 20 is temporarily bypassed so as not to impair the output of unshaded segments 19, 20 of the solar cell array 2.

The figures show that there is a distance of several rows 6 of solar cells 3 between two cross-connectors 4, 9 made of electrically conductive adhesive tape 5, 7. At least one cross-connector, namely the initial cross-connector 9 made of electrically conductive, double-sided adhesive tape 7, is arranged on the sunny side 15 of the solar cell arrays 2. The remaining cross-connectors 4 made of electrically conductive adhesive tape 5 and also the longitudinal connectors 10 are arranged on the rear side 14 of the solar cell arrays 2, which faces away from the sunny side 15 of the solar cell arrays 2.

The solar cell arrays 2 of the solar panels 1 shown in the figures can be cross-connected according to the method described below for cross-connecting a solar cell array 2 of crystalline solar cells 3.

Cross-connectors 4,9 made of electrically conductive adhesive tape 5,7 are used for cross-connecting the solar cell array 2. The cross-connectors 4, 9 made of electrically conductive adhesive tape are each bonded to a row 6 of solar cells 3. The cross-connectors 4, 9 are bonded in this case to the rows 6 of solar cells 3 in such a way that they extend within their respective row 6 without contacting or overlapping adjacent rows of solar cells 3.

One cross-connector, namely the initial cross-connector 9 made of electrically conductive adhesive tape 7, is bonded to a sunny side 15 of a row 6. The remaining cross-connectors 4 made of electrically conductive adhesive tape 5 are bonded to a rear side 14 of rows 6 of solar cells 3 facing away from the sunny side 15.

The cross connector labeled 9 is bonded as an initial cross connector to the support structure 8 of the solar panel 1 for the solar cell array 2 before the solar cell array 2 is positioned on the support structure 8. This initial cross-connector 9 consists of double-sided, electrically conductive adhesive tape 7, so that the initial cross-connector 9 according to FIG. 7 can adhere to the support structure 8 itself and provides an adhesive surface on its free surface, which can be used for connection to a first row 6 of solar cells 3 of the solar cell array 2.

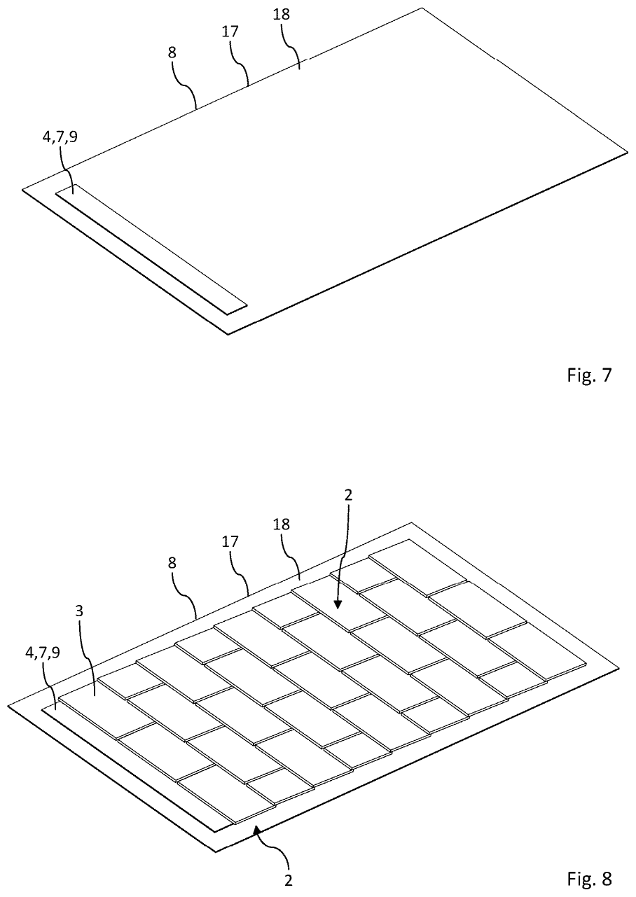

The support structure 8 of the solar panel 1 shown in the figures consists of a glass pane 17, which is shown in FIG. 5, and a plastic film 18, namely an EVA film or a PCB film, which is shown in FIG. 6. The initial cross-connector 9 is bonded to the plastic film 18 of the support structure 8. The solar cell array 2 is then placed with the sunny side 15 of an edge-side row 6 of solar cells 3 on the initial cross-connector 9 and the initial cross-connector 9 is bonded to the edge-side row 6 of the solar cell array 2.

The cross-connectors 4, 9 made of electrically conductive adhesive tape 5, 7 are bonded to different rows 6 of solar cells 3 of the solar cell array 2 in order to divide the solar cell array 2 into individual segments 19 and 20. The cross-connectors 4, 9 are bonded to the rows 6 of the solar cell array 2 at a distance of several rows 6 of solar cells 3 from each other.

Before the cross-connectors 4 are bonded to the rows 6, gaps 12 between adjacent solar cells 3 of a row 6 onto which a cross-connector 4 is to be bonded are first optically closed by cover elements 13, namely by masking adhesive strips, as shown in FIG. 9. The cross connectors 4 are then bonded to the rows 6 and the already bonded-on cover elements 13. The cross-connectors 4 are then covered by the cover elements 13 and, when viewed from a sunny side 15 of the solar cell array 2, are no longer visible through the gaps 12.

Like the cross-connectors 4, the cover elements 13 are also bonded to the rear side 14 of the solar cell array 2.

The cross-connectors 4, 9 are each electrically connected to a longitudinal connector 10 for connection to a junction box. Like the cross-connectors 4, the longitudinal connectors 10 are also made of electrically conductive adhesive tape 5.

In the solar panel 1 shown in FIG. 4, the cross-connectors 4, 9 are bonded to the rows 6 and the support structure 8 with an overhang over one end 21 of the rows 6. The protruding section of the cross-connectors 4, 9 is then used to connect to the longitudinal connectors 10.

The longitudinal connectors 10 are either placed at right angles to a row orientation of the rows 6 of the solar cell arrays 2, namely bonded, or bonded next to the solar cell arrays 2 on the support structures 8 of the solar panels 1 for the solar cell arrays 2.

Before the longitudinal connectors 10 are placed over the solar cells 3, insulators 11, which consist of insulating adhesive tape, are first bonded to the rows 6 between two cross-connectors 4, 9 at right angles to a row orientation of the rows 6. The longitudinal connectors 10 are then bonded to the insulators 11 and the cross-connectors 4,9.

In the embodiments of solar panels 1 shown in the figures, the solar cells 3 of the solar cell arrays 2 are arranged in a shingle-matrix arrangement.

The method explained above is illustrated with reference to FIGS. 5 to 12. First, a glass pane 17 is provided as part of the support structure 8. The plastic film 18 shown in FIG. 6 can then be applied to the glass pane 17.

As shown in FIG. 7, the plastic film 18 is first covered with the initial cross-connector 9, which consists of electrically conductive, double-sided adhesive tape 7, in a work step. As shown in FIG. 8, the solar cell array 2 is then placed on the plastic film 18 serving as the support structure 8, wherein an edge-side row 6 of the solar cell array 2 is placed with its sunny side 15 on the initial cross-connector 9 and the initial cross-connector 9 is bonded to the edge-side row 6 of the solar cell array 2.

According to 9, the cover elements 13 are then applied in the form of adhesive cover strips in order to optically close gaps 12 between adjacent solar cells 3 of a row 6 that is to be bonded with a cross-connector 4.

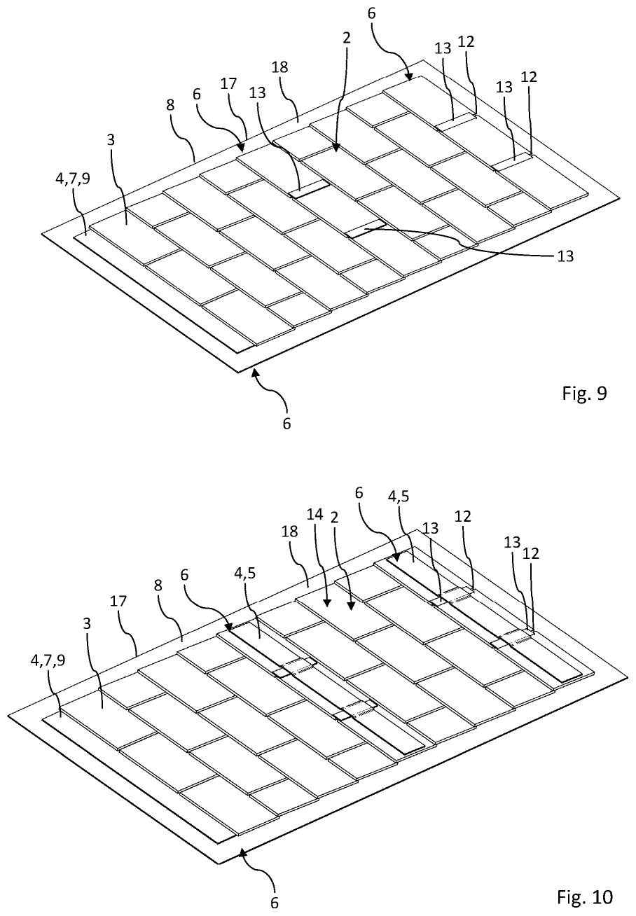

According to FIG. 10, in addition to the initial cross-connector 9, further cross-connectors 4 are then bonded to the rows 6 with the optically closed gaps 12. The cross-connectors 4 are then no longer visible when viewed from the sunny side 15 of the solar cell array 2, as they are arranged behind the solar cells 3 and the cover elements 13.

In a subsequent method step, the insulators 11 in the form of strips of insulating adhesive tape are bonded to the rows 6 of solar elements 3 located between two cross-connectors 4, 9 on the rear side 14 of the solar cell array 2.

The insulators 11 are aligned at right angles to the row orientation of the rows 6. Finally, FIG. 12 shows the cross-connected solar cell array 2 after the longitudinal connectors 10 have been applied. Junction boxes 16 can be connected to the longitudinal connectors 10 at the positions marked 160.

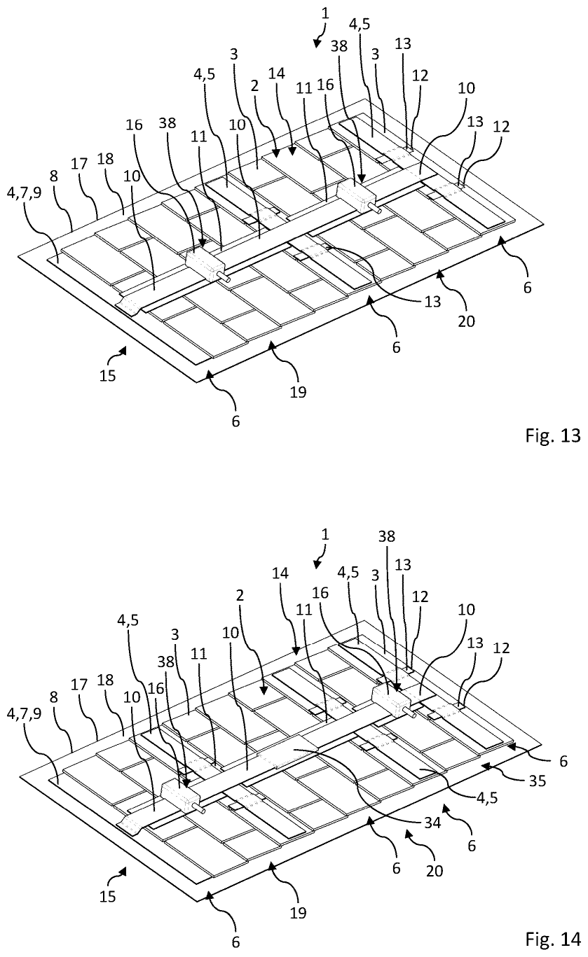

FIG. 13 shows the solar cell array 2 illustrated in FIG. 12, with junction boxes 16 arranged at the positions labeled 160 in FIG. 12. The junction boxes 16 are electrically connected to the cross-connectors 4, 9 via the longitudinal connectors 10. The junction boxes 16 contain bypass diodes 38, with which the bypass circuit explained above can be realized in the event of partial shading of one of the two segments 19 and 20 of the solar cell array 2.

FIG. 14 shows a further embodiment of a solar cell array 2 cross-connected to a total of four cross-connectors 4, 9.

This solar cell array 2 is divided into a total of three segments 19, 20 and 35 of solar cells 3 by a cross-connector 4, which was bonded to the support structure 8 as an initial cross-connector 9, and three further cross-connectors 4, which are bonded to a rear side 14 of the solar cell array 2 or the rows 6 of solar cells 3.

The first segment 19 and the third segment 35 are each assigned a junction box 16. The junction boxes 16 are connected to the cross-connectors 4, 9 or 4 via longitudinal connectors 10.

The two cross-connectors 4, which delimit the second or middle segment 20 of the solar cell array 2, are connected via longitudinal connectors 10 to a flat diode 34, which functions as a bypass diode. Due to its low height, this flat diode 34 can be laminated into the finished solar panel 1 after application of a plastic film 36 on the rear side, which can be an EVA plastic film or a PCB plastic film, and optionally a support layer 37 on the rear side.

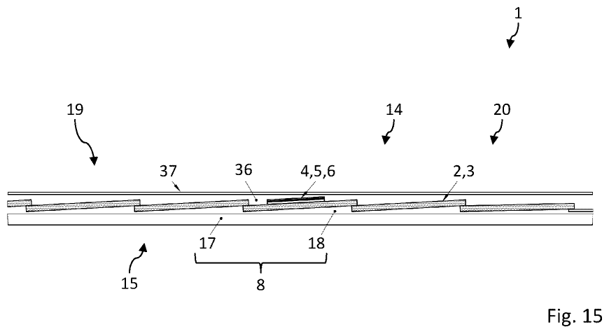

FIG. 15 shows a cross-section of a solar panel 1, which has a cross-connected solar cell array 2, as shown in the previous figures in various embodiments. FIG. 15 clearly shows the layered structure of the solar panel 1.

The support structure 8 of the solar panel 1 for the solar cell array 2, made of the glass pane 17 and the plastic film 18, can be seen on the sunny side 15 of the solar cell array 2. The solar cell array 2 made of rows 6 of crystalline solar cells 3 is placed on the plastic film 18.

A central row 6 of solar cells 3 of the section of the solar cell array 2 shown in FIG. 15 has a cross-connector 4 made of electrically conductive adhesive tape 5 bonded to its rear side 14. The solar cell array 2 shown in FIG. 15 is thus divided into at least two segments 19 and 20. The rear side 14 of the solar cell array 2 is covered with a plastic film 36 on the rear side, for example an EVA film or also a PCB film. A rear-side support layer 37 is applied to the rear plastic film 36. The cross-connected solar cell array 2 is then laminated between the two plastic films 18 and 36 in the finished solar panel 1.

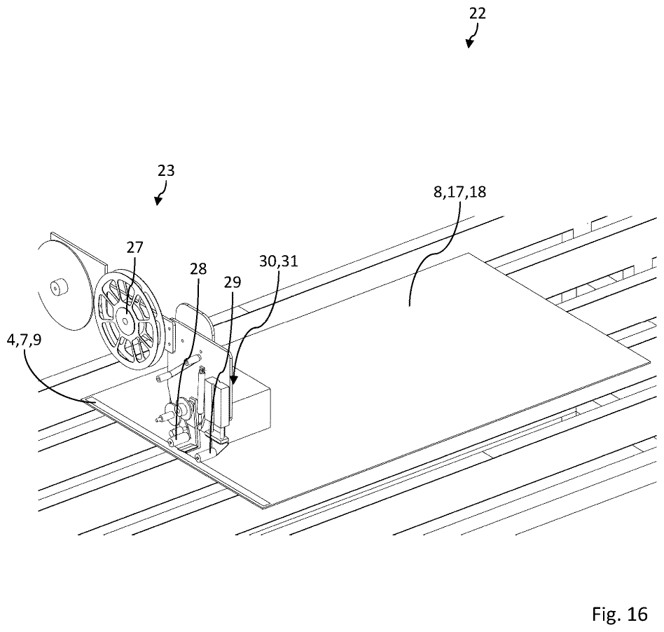

FIGS. 16-22 show details of a device, referred to as a whole as 22, for the electrical cross-connection of solar cell arrays 2 made of crystalline solar cells 3. The device 22 is set up to carry out the method explained above and has several cross-connector applicators 23, which are set up to stick electrically conductive adhesive tape 5, 7 as cross-connectors 4, 9 onto rows 6 of solar cell arrays 2 and/or onto support structures 8 for solar cell arrays 2.

FIG. 16 shows a cross-connector applicator 23 which is set up for bonding electrically conductive, double-sided adhesive tape 7 as an initial cross-connector 9 onto support structures 8 for solar cell arrays 2.

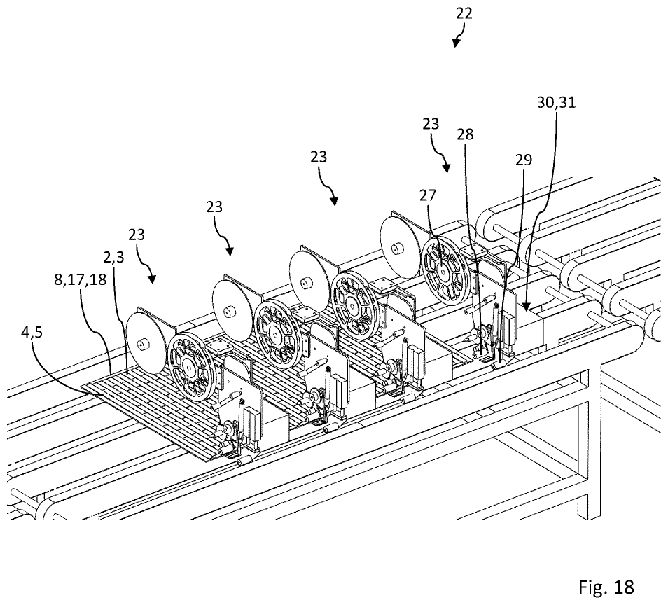

FIG. 18 shows cross-connector applicators 23, which are set up to stick electrically conductive adhesive tape 5 as further cross-connectors 4 onto rows 6 of solar cell arrays 2.

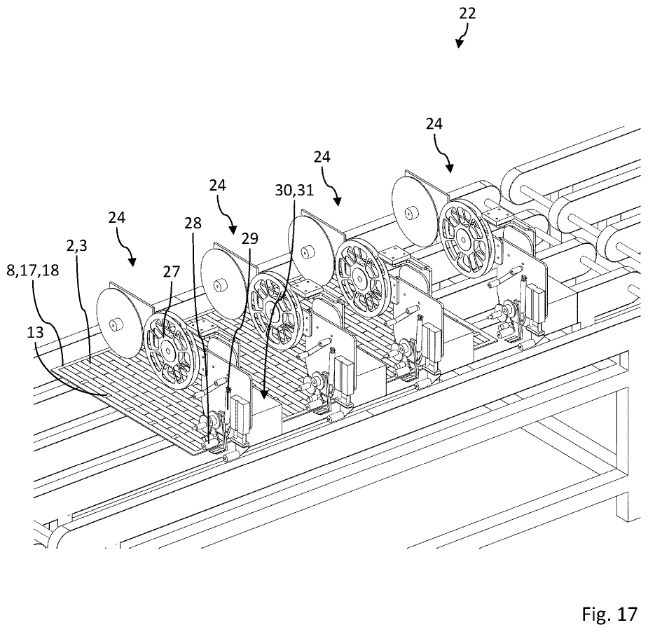

The device 22 also has cover element applicators 24. These are shown in FIG. 17 and are designed to apply cover elements 13 to gaps 12 between adjacent solar cells 3 of a row 6 of solar cells 3.

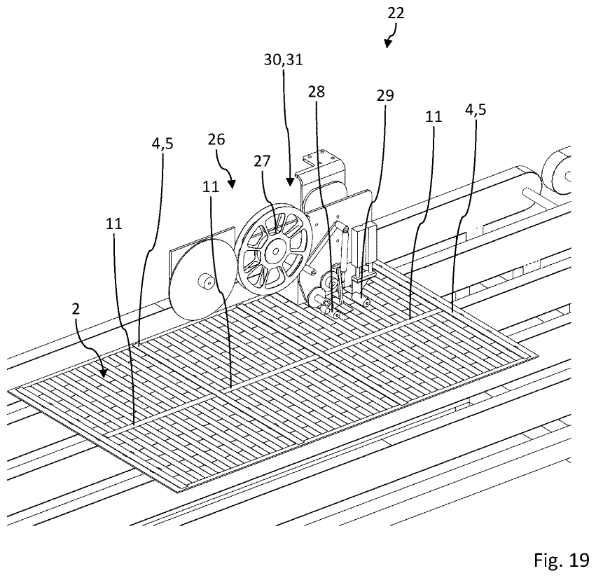

FIG. 19 shows an insulation applicator 26 of the device 22, which is set up for gluing on electrical insulators 11 made of insulating adhesive tape. FIG. 19 shows the insulation applicator 26 after the application of the insulators 11.

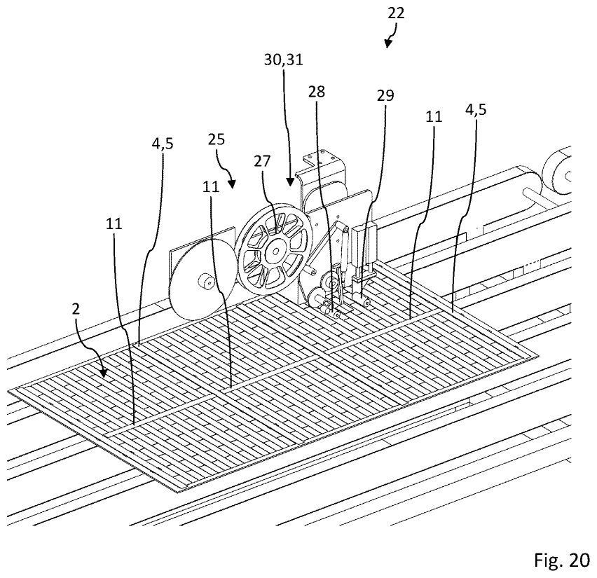

The device 22 also has at least one longitudinal connector applicator 25, which is shown in FIG. 20 before the application of longitudinal connectors 10. The longitudinal connector applicator 25 is adapted for adhering longitudinal connectors 10 to the solar cell arrays 2 and/or to support structures 8 for the solar cell arrays 2.

All of the aforementioned applicators 23, 24, 25 and 26 have a comparable structure. Each of the applicators 23, 24, 25 and 26 of the device 22 has a supply roller 27, an application element 28, namely an application roller, and a pressure element 29, namely a pressure roller downstream of the application element 28 in the application direction.

The adhesive tapes used as cross-connectors 4, initial cross-connectors 9, longitudinal connectors 10 or insulators 11 can be unrolled from the supply roller 27 and applied with the respective application element 28. The downstream pressure element 29 then presses the adhesive tapes onto the surfaces to be bonded after they have been applied. This increases the adhesive effect of the adhesive tapes on the respective surface.

The respective adhesive tapes 4, 9, 10, 11 and 13 can be pre-assembled in the required length and rolled up on the respective supply roller. However, it is also possible for the device 22 to have a cutting device for cutting the adhesive tapes 4, 9, 10, 11 and 13 to length for each applicator 23, 24, 25 and 26.

The device 22 is also set up to monitor the pressure of the cross-connector applicators 23, the cover element applicator 24, the longitudinal connector applicator 25 and the insulation applicator 26 in order to protect the solar cells 3 from damage when applying the adhesive tapes 4, 9, 10, 11 and 13.

The device 22 has at least one pressure sensor 30 for each cross-connector applicator 23, for each cover element applicator 24, for each longitudinal connector applicator 25 and for each insulation applicator 26, with which the pressure exerted on the solar cells 3 during the application of the cross-connectors 4, 9, the cover elements 13, insulators 11 and/or longitudinal connectors 10 can be monitored.

Control units 31 of the applicators 23, 24, 25 and 26 of the device 22 are set up to regulate and reduce the pressure of the applicators 23, 24, 25 and 26 during application if a permissible maximum pressure is exceeded during application.

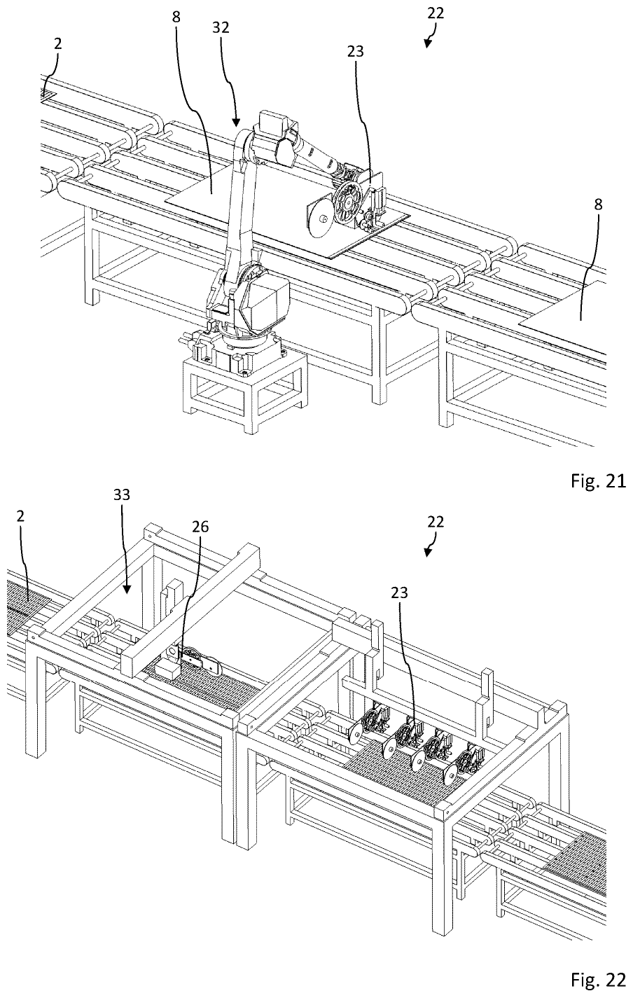

FIG. 21 shows a device 22 with a cross-connector applicator 23 on a robot 32. FIG. 22 shows a device 22 with a portal 33 on which cross-connector applicators 23 and an insulation applicator 26 are arranged.

The invention relates to improvements in the technical field of manufacturing solar panels. Among other things, a method for cross-connecting a solar cell array 2 comprising crystalline solar cells 3 is proposed for this purpose, in which at least one cross-connector 4, 9 made of electrically conductive adhesive tape 5, 7 is used for cross-connection.

### LIST OF REFERENCE SIGNS

1 Solar panel
2 Solar cell array
3 Solar cell
4 Cross-connector
5 Electrically conductive adhesive tape
6 Row of solar cells in 2
7 Electrically conductive, double-sided adhesive tape
8 Support structure
9 Initial cross-connector
10 Longitudinal connector
11 Insulator, insulation tape
12 Gap
13 Cover element
14 Rear side
15 Sunny side
16 Junction box
160 Position of a junction box
17 Glass pane
18 Plastic film
19 First segment of 2
20 Second segment of 2
21 End of row
22 Device
23 Cross-connector applicator
24 Cover element applicator
25 Longitudinal connector applicator
26 Insulation applicator
27 Supply roller
28 Application element
29 Pressure element
30 Pressure sensor
31 Control unit
32 Robot
33 Portal
34 Flat diode
35 Third segment of 2
36 Rear-side plastic film
37 Rear-side support layer
38 Bypass diode

1. A method for cross-connecting a solar cell array (2) made of crystalline solar cells (3), the method comprising: using at least one cross-connector (4, 9) made of electrically conductive adhesive tape (5, 7) for cross-connecting the solar cell array (2).

2. The method according to claim 1, further comprising bonding the at least one cross-connector (4, 9) made of the electrically conductive adhesive tape to a row (6) of the solar cells (3).

3. The method according to claim 2, wherein the at least one cross-connector (4, 9) made of the electrically conductive adhesive tape (5, 7) is bonded to a sunny side (15) of the row (6) or to a rear side (14) of the row (6) facing away from the sunny side (15).

4. The method according to claim 1, wherein the cross-connector (4, 9) made of the electrically conductive adhesive tape (7) is bonded as an initial cross-connector (9) onto a support structure (8) for the solar cell array (2), and the method further comprises placing the solar cell array (2 on the initial cross-connector (9) and the initial cross-connector (9) is bonded to a row (6) of the solar cell array (2).

5. The method according to claim 1, further comprising at least two or more cross-connectors (4, 9) made of the electrically conductive adhesive tape (5, 7) are bonded to different rows (6) of the solar cells (3).

6. The method according to claim 1, further comprising placing cover elements (13) over gaps (12) between adjacent ones of the solar cells (3) of a row (6) before the cross-connector (4,9) made of the electrically conductive adhesive tape (5, 7) is bonded to the row (6), and the cover elements (13) are applied to a rear side (14) of the solar cell array (2) which faces away from a sunny side (15) of the solar cell array (2).

7. The method according to claim 1, further comprising electrically connecting one of the cross-connectors (4, 9) for connection to a junction box to a longitudinal connector (10).

8. The method according to claim 7, further comprising using an adhesive strip of electrically conductive adhesive tape (5) as the longitudinal connector (10).

9. The method according to claim 1, wherein at least one said cross-connector (4, 9) is bonded to a row (6) with an overhang over a row end (21) of a row (6) of the solar cells (3).

10. The method according to claim 1, further comprising placing at least one longitudinal connector (10) transversely or at right angles to a row orientation of the solar cell array (2) over rows (6) of the solar cells (3), or placing a longitudinal connector (10) transversely or at right angles to a row orientation of the solar cell array (2) on a support structure (8) adjacent to the solar cells (3) of the solar cell array (2).

11. The method according to claim 1, further comprising placing an electrical insulator (11) transversely or at right angles to a row orientation of rows (6) of the solar cells (3) on the rows (6) between two of the cross-connectors (4, 9), and placing at least one longitudinal connector (10) on at least one of the electrical insulator (11) or one of the cross-connectors (4, 9).

12. The method according to claim 1, wherein the solar cells (3) of the solar cell array (2) are arranged in a shingle-matrix arrangement.

13. A solar panel (1) comprising: a solar cell array (2) made of crystalline solar cells (3), and at least one cross-connector (4) made of electrically conductive adhesive tape to which the solar cell array (2) is cross connected.

14. The solar panel (1) according to claim 13, wherein the at least one cross-connector (4) made of electrically conductive adhesive tape (5) is bonded to a row (6) of solar cells (3).

15. The solar panel (1) according to claim 13, wherein at least one of a) the at least one cross-connector (4) consists of electrically conductive, double-sided adhesive tape (7), b) the solar cells (3) of the solar cell array (2) are arranged in a shingle-matrix arrangement, and an electrical voltage build-up takes place transversely or at right angles to an alignment of rows (6) of the solar cells (3) via rows (6) of the solar cell array (2), or c) an electrical voltage level is present within a row (6) of solar cells (3) of the solar cell array (2).

16. The solar panel (1) according to claim 13, wherein the at least one cross-connector (4, 9) is made of electrically conductive adhesive tape (5, 7), and is connected to a longitudinal connector (10).

17. The solar panel (1) according to claim 16, wherein the longitudinal connector (10) extends transversely or at right angles to a row orientation of rows (6) of solar cells (3), which are arranged between two cross-connectors (4, 9).

18. The solar panel (1) according to claim 17, further comprising an insulator (11) arranged between the longitudinal connector (10) and the rows (6) of the solar cells (3).

19. The solar panel (1) according to claim 13, wherein gaps (12) between adjacent solar cells (3) of a row (6) bonded with the at least one cross-connector (4, 9) of the electrically conductive adhesive tape (5, 7) are covered with cover elements (13), and the cover elements (13) are arranged on a rear side (14) of the solar cell array (2) which faces away from a sunny side (15) of the solar cell array (2).

20. The solar panel (1) according to claim 13, wherein two of the cross-connectors (4, 9) are connected to one another via longitudinal connectors (10) and at least one of a junction box or a bypass circuit.

21. The solar panel (1) according to claim 13, wherein between two of the cross-connectors (4, 9) made of the electrically conductive adhesive tape (5, 7) there is a spacing of at least one row (6) of the solar cells (3).

22. The solar panel (1) according to claim 13, wherein at least one of a) at least one of the cross-connectors (5, 9) made of the electrically conductive adhesive tape (7) is arranged on a sunny side (15) of the solar cell array (2), or b) at least one of the cross-connectors (4) made of the electrically conductive adhesive tape (5) and/or a longitudinal connector (10) is arranged on a rear side (14) of the solar cell array (2) facing away from a sunny side (15) of the solar cell array (2).

23. A device (22) for electrical cross-connection of solar cell arrays (2), wherein the device (22) is set up for carrying out the method according to claim 1 and comprises at least one cross-connector applicator (23) which is set up for bonding the electrically conductive adhesive tape (5, 7) as the cross-connectors (4, 9) onto at least one of rows (6) of the solar cell arrays (2) or support structures (8) for the solar cell arrays (2).

24. A device (22) according to claim 23, further comprising at least one cover element applicator (24) which is set up to apply cover elements (13) onto gaps (12) between adjacent ones of the solar cells (3) of a row (6) of the solar cell arrays (2).

25. The device (22) according to claim 24, further comprising at least one longitudinal connector applicator which is set up for applying longitudinal connectors (10).

26. The device (22) according to claim 25, further comprising at least one insulation applicator (25) for applying electrical insulators (11).

27. The device (22) according to claim 26, wherein at least one of the cross-connector applicator (23), the cover element applicator (24), the longitudinal connector applicator (25) or the insulation applicator (26) comprises at least one of a supply roller (27), an application element (28), or a pressure element (29.

28. The device (22) according to claim 27, further comprising at least one pressure sensor (3) for monitoring a pressure of at least one of the cross-connector applicator (23), the cover element applicator (24), the longitudinal connector applicator (25) or the insulation applicator (26), with which the pressure acting on the solar cells (3) during the application of the at least one of the cross-connectors (4, 9), the cover elements (13), the insulators (11) or the longitudinal connectors (10) is adapted to be monitored.
